(19) United States
(12) Patent Application Publication
(10) Pub. No.: US 2003/0217698 A1
(43) Pub. Date: Nov. 27, 2003

(54) Plasma chemical vapor deposition apparatus

(76) Inventors: Ryoichi Hiratsuka, Miyagi (JP); Taketoshi Sato, Miyagi (JP); Takashi Watanabe, Miyagi (JP); Toshihiro Konishi, Miyagi (JP)

Correspondence Address: Robert J. Depke, Holland & Knight LLC, 30th Floor, 131 South Dearborn Street, Chicago, IL, 60603-5506, US

(21) Appl. No.: 10/437,505

(22) Filed: May 14, 2003

(30) Foreign Application Priority Data
May 23, 2002 (JP) P2002-149631

(51) Int. Cl. C23C 16/00

(52) U.S. Cl. 118/723 E; 118/718

(57) ABSTRACT

A reactor for generating plasma is provided in a vacuum chamber. The reactor has an opening in the direction of a supporting portion for a deposition base material, and the reactor includes an outer housing and a cylindrical inner wall structure that is inserted in the outer housing and is freely attachable and detachable to and from the outer housing. The cleaning of the reactor is performed with respect to the cylindrical inner wall structure that is simpler in structure than the outer housing, and hence the reactor can be cleaned reliably and with ease, thereby making it possible to improve the operational efficiency and the yield rate. The problem of prolonged operation time resulting from the cleaning of the reactor in a plasma chemical vapor deposition apparatus is thus resolved.

### CROSS REFERENCE TO RELATED APPLICATIONS

The present document claims priority to Japanese Priority Document JP 2002-149631, filed in the Japanese Patent Office on May 23, 2002, the entire contents of which are incorporated herein by reference to the extent permitted by law.

### BACKGROUND OF THE INVENTION

1. Field of the Invention

The present invention relates to a plasma chemical vapor deposition (CVD) apparatus which is suitable for use in the deposition of, for example, a protective film in manufacturing magnetic recording media.

2. Description of the Related Art

As high-density magnetic recording media, so-called metallic magnetic thin-film type magnetic recording media are conventionally known.

This metallic magnetic thin-film type magnetic recording medium includes a non-magnetic support member, such as, for example, a polyester film, a polyamide film, or a polyimide film, on which is deposited, as a metallic magnetic thin-film, a metal magnetic material, such as a Co—Ni alloy, a Co—Cr alloy, or Co—O, by way of plating or a vacuum thin-film deposition process, including for example, a vacuum deposition (evaporation) process, a sputtering process, an ion plating process and the like.

Such metallic magnetic thin-film type magnetic recording media have superior coercive force and squareness ratio, and can be made extremely thin. Therefore, they have numerous advantages in realizing high-density recording since the demagnetization during recording and the thickness loss during reading are extremely small and the electromagnetic conversion characteristics at short wavelengths are excellent. In addition, there is no need to incorporate a binder of a non-magnetic material into the magnetic layer of the magnetic recording media, and therefore the packing density of the magnetic materials in the recording media can be increased.

Thus, since metallic magnetic thin-film type magnetic recording media have numerous superior magnetic properties, they are becoming mainstream in high-density magnetic recording media.

For magnetic recording media, even higher degrees of high-density recording are being demanded. In order to meet such demands, there is a trend towards smoother medium surfaces for purposes of reducing spacing loss.

However, as the surface of a magnetic recording medium becomes smoother, the friction between the magnetic recording medium and a read and/or write magnetic head, which contacts the medium, becomes larger, and the shear stress experienced by the medium becomes larger. Therefore, higher durability is demanded for these magnetic recording media.

As a method for enhancing the durability of these magnetic recording media, a technology for forming a protective film on the surface of the magnetic layer is being studied.

Protective films formed with, for example, a carbon film, a quartz (SiO₂) film, and a zirconia (ZrO₂) film are known.

These materials have already been used in, for example, hard disks. More specifically, recently, of the various carbon films, hard carbon films having a diamond structure, or so-called diamond-like carbon films are being viewed favorably for this purpose, and it is considered that they will be widely used in the future.

Examples of processes for depositing a hard carbon protective film include a sputtering process, a chemical vapor deposition (CVD) process and the like.

In the sputtering process, a sputter gas, such as argon (Ar) gas, is ionized, or plasmarized, and accelerated using an electric field or a magnetic field, and is bombarded on a target surface to sputter atoms from the target. These atoms are deposited on a base material to form a protective film.

However, forming a hard carbon film by the sputtering process is generally slow, and is thus inferior in terms of productivity, and has problems for industrial use.

On the other hand, in the plasma CVD process, a reactant gas, which is to form a film, is subjected to a chemical reaction, such as decomposition or synthesis, by way of the energy of plasma generated in an electric field. The product formed by this chemical reaction is deposited on a deposition base material to form a CVD film.

The plasma CVD process has a higher deposition rate as compared to the sputtering process, and therefore it is seen as a promising option for depositing hard carbon films.

In a plasma CVD apparatus for depositing a hard carbon protective film or the like mentioned above, there is provided a cylindrical rotational support, or a so-called rotational cooling can, inside a vacuum chamber where the rotational support forms a unit for supporting a deposition base material onto which a film is deposited by CVD. In this apparatus, a strip-shaped deposition base material, which forms, for example, a magnetic recording medium, runs around the circumference of the rotational support, and a reactor for generating plasma is disposed so as to face the deposition base material.

A reactant gas is fed to the reactor, and plasma is generated between the deposition base material and a discharge electrode provided in the reactor. The reactant gas is subjected to a chemical reaction, such as decomposition or synthesis, and a film is formed by continuously depositing the product of this reaction on the deposition base material that runs around the circumference of the rotational cooling can.

### SUMMARY OF THE INVENTION

When a CVD process is performed by this CVD apparatus over a short period of time, since contamination due to the accumulation of dirt in the reactor for generating plasma would be relatively light, the required cleaning would be brief. However, in practice, CVD processes would be repeated a plurality of times, the result of which is accumulated dirt inside the reactor. The accumulated dirt then peels off the reactor during CVD processes and contaminates CVD films or becomes mixed in or adheres to the CVD film, thereby compromising the quality or purity of the film, causing wrinkles in the film, and the like.

For this reason, the reactor in the CVD process is cleaned periodically. This cleaning takes a considerable amount of time due to the shape and position of the reactor, and as a result, advantages of the CVD process, namely its high deposition rate, cannot fully be taken advantage of.

A plasma CVD apparatus according to an embodiment of the present invention includes a vacuum chamber, a unit in the vacuum chamber for supporting a deposition base material on which a film is deposited, and a reactor for generating plasma having an opening in the direction of the deposition base material on the support unit.

In the embodiment of the present invention having the configuration described above, a separable structure is adopted for the reactor, where the reactor includes an outer housing and a cylindrical inner wall structure which is inserted inside the outer housing so as to be freely attachable and detachable, and thus the reactor can be separated into a plurality of parts.

The outer housing has an opening in the direction of the deposition base material, and has an inlet for receiving plasma CVD reactant gas.

The cylindrical inner wall structure is such that at least the surface thereof has electrically insulative properties, is formed in a cylinder following the shape of the inner wall of the outer housing, and surrounds section where plasma is generated.

In the outer housing, a grid electrode forming a discharge electrode is disposed in another opening in the cylindrical inner wall structure on a side opposite the opening in the direction of the deposition base material.

Thus, in this embodiment, the reactor is configured with the outer housing and the cylindrical inner wall structure which is inserted inside the outer housing so as to be freely attachable and detachable and so as to surround the section where the reaction takes place. Therefore, most of the products are accumulated on the cylindrical inner wall structure.

Thus, the cylindrical inner wall structure can be taken out from the outer housing, and the accumulated dirt can be cleaned from the cylindrical inner wall structure.

Thus, the time required to clean the dirt from the plasma reaction off the reactor can be shortened, thereby making it possible to minimize the time loss resulting from cleaning, and operational efficiency and productivity can be improved.

In addition, since the reactor can be cleaned thoroughly, the apparatus can be applied to, for example, the manufacture of magnetic recording media while lowering the percentage of defective products.

Further, when the cylindrical inner wall structure is given a thermal conductivity of 14.2 [W·m⁻¹·k⁻¹] or above, occurrences of wrinkles in the film during deposition can be suppressed to thereby lower the defective percentage still further.

### BRIEF DESCRIPTION OF THE DRAWINGS

The above and other aspects, features and advantages of the present invention will become more apparent from the following description of the presently preferred exemplary embodiments of the invention taken in conjunction with the accompanying drawings, in which:

FIG. 1 is a schematic view showing an example of a configuration of plasma CVD apparatus according to an embodiment of the present invention;

FIG. 2 is a perspective view of an example of a reactor in the plasma CVD apparatus according to an embodiment of the present invention;

FIG. 3 is a graph showing the relationship between reactor temperatures in examples of the present invention and in comparative examples; and

FIG. 4 is a graph showing the measurement results of the relationship between the defective percentage and the thermal conductivity of the cylindrical inner wall structures in the reactors of the examples of the present invention and of the comparative examples.

### DETAILED DESCRIPTION OF THE PREFERRED EMBODIMENTS

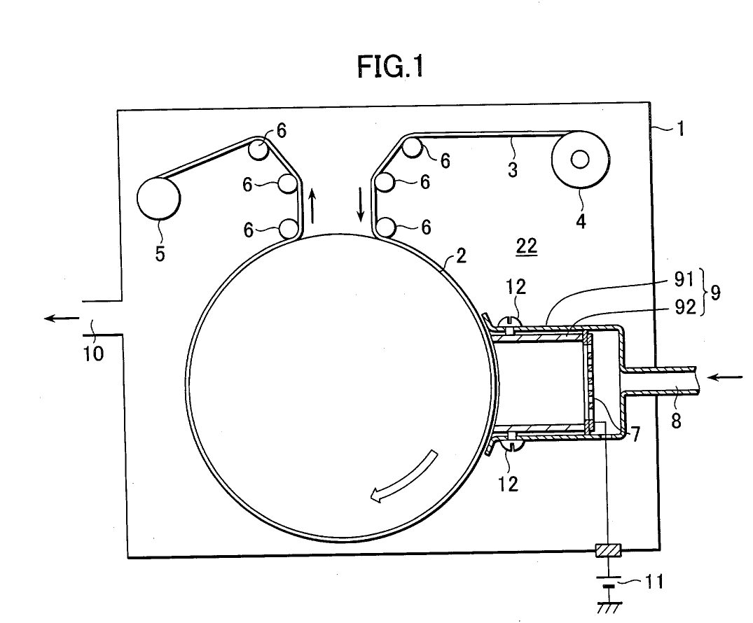

Hereinbelow, a preferred embodiment of the apparatus of the present invention will be described in detail with reference to the schematic view shown in FIG. 1. However, it is to be understood that the present invention is not limited thereto.

In the construction shown in FIG. 1, there is provided a cylindrical rotational support member 2 inside a vacuum chamber 1. The rotational support member 2 may be configured with, for example, a cooling can, and forms a support section 22 for a strip-shaped deposition base material 3 onto which a film is deposited by CVD. The deposition base material 3 is guided by a plurality of guide rollers 6 so that the base material 3 runs smoothly around the circumference of the rotational support member 2 and is transferred from a supply roll 4 to a take-up roll 5 while maintaining an appropriate tension.

A discharge electrode 7 is housed in a reactor 9 for generating plasma, and a reactant gas is fed to the reactor 9 from a reactant gas inlet 8. The reactor 9 is provided in the vacuum chamber 1 such that the reactor faces the deposition base material 3 on the circumference of the rotational support member 2, while maintaining a gap of, for example, several mm to about 1 cm therebetween.

An exhaust vent 10 connected to an exhaust means (not shown) is provided in the vacuum chamber 1, and exhausts the vacuum chamber 1 to maintain predetermined vacuum conditions inside the vacuum chamber 1.

The deposition base material 3 includes a metallic magnetic thin-film deposited on, for example, a non-magnetic support member.

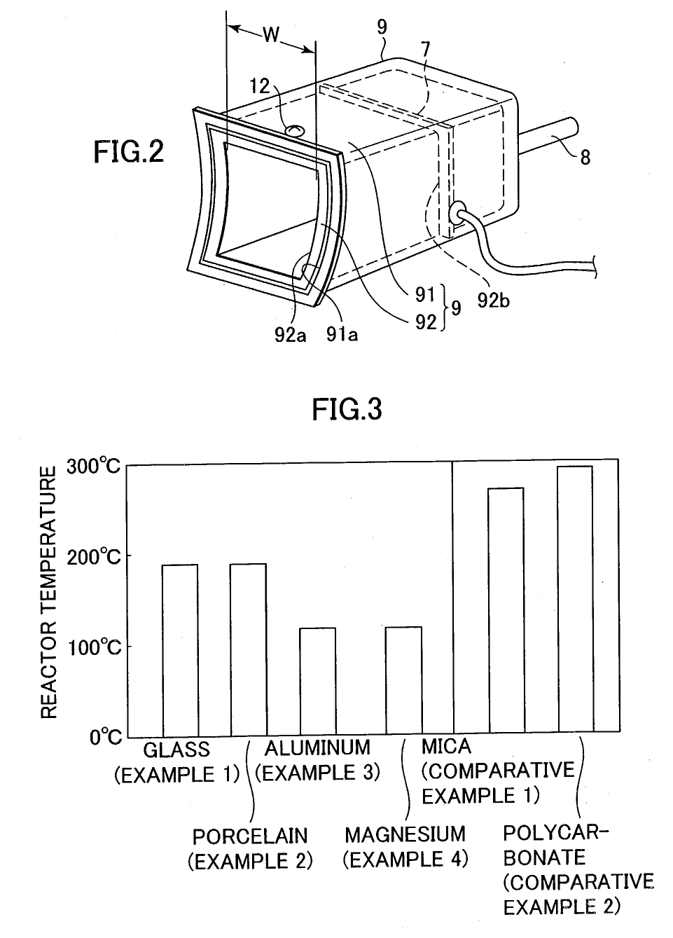

In the present invention, the reactor 9 has a separable structure where it can be separated into a plurality of parts including an outer housing 91 and a cylindrical inner wall structure 92. Specifically, for example, as shown in the schematic perspective view of FIG. 2 illustrating an example of the reactor 9, the outer housing 91 has an opening 91a which opens towards the deposition base material 3 on the surface of the rotational support member 2 shown in FIG. 1, and the cylindrical inner wall structure 92 has an opening 92a which follows the shape of the opening 91a of the outer housing 91, and the cylindrical inner wall structure 92 is insertable inside the outer housing 91 so as to be freely attachable and detachable and is disposed in the outer housing 91 along the inner wall of the outer housing 91 so as to enclose the section where plasma is generated in the reactor 9.

The cylindrical inner wall structure 92 can be secured with screws 12 while inserted, as shown in FIG. 1, inside the outer housing 91.

The front end of the opening in the reactor 9, that is, the front ends of the openings 91a and 92a are individually curved along the curved surface of the rotational supportive member 2 on which the deposition base material 3 is supported.

The width W of the opening 92a of the cylindrical inner wall structure 92 is set to be such that it covers at least the width of the region of the deposition base material 3 on which a film is deposited by CVD. For example, the width W of the opening 92a is set to be such that it covers the entire width of the strip-shaped deposition base material 3.

The cylindrical inner wall structure 92 may be formed with an insulative material, but it may also have a composite structure having electrically insulative properties, where a metal with a high thermal conductivity is taken as a core material and the entire surface of the core material, in other words, the inner and outer surfaces, as well as the surface of the opening, is covered with an insulative material layer.

The insulative material forming the cylindrical inner wall structure 92 may contain, for example, quartz glass, porcelain, alumina, silicon, germanium, rock crystal, calcite, or fluorite.

Aluminum, iron, copper, titanium, magnesium, nickel, brass, gold, silver, or stainless steel may be used for the core material metal.

It is preferable that the cylindrical inner wall structure 92 be formed with a material having a thermal conductivity of 14.2 [W·m⁻¹·k⁻¹] or above. By forming the cylindrical inner wall structure 92 with a material having a high thermal conductivity, the heat radiation effect is improved, thereby preventing a rise in radiant heat inside the reactor due to plasma reaction heat, and thus making it possible to reduce film defects during deposition.

In an opening 92b on the side opposite the opening 92a of the cylindrical inner wall structure 92, the discharge electrode 7, in other words the grid electrode plate, is disposed along a plane perpendicular to the axis of the reactor 9 and such that it is insulated from the outer housing 91.

It is preferable that the discharge electrode 7 be an electrode plate, for example, a mesh electrode, that has a high permeability for gas, is capable of applying a uniform electric field and is flexible. For example, the discharge electrode 7 may adopt a mesh configuration in which numerous holes with a diameter of, for example, 2 mm are opened in a copper plate. Alternatively, the discharge electrode 7 may also be formed with various conductive metals, such as stainless steel, brass, gold and the like.

A direct current (DC) power source 11 is connected to the discharge electrode 7.

The discharge electrode 7 is not limited to the single-plate structure shown in the drawings, and instead may be a multi-plate structure.

In this CVD apparatus, desired vacuum conditions are maintained inside the vacuum chamber 1, and a desired reactant gas is fed to the reactor 9 and plasma is generated between the deposition base material 3 and the discharge electrode 7 so that the plasma causes the reactant gas to undergo a chemical reaction, such as decomposition or synthesis, mainly within the cylindrical inner wall structure 92. As a result, the product of the chemical reaction can be continuously deposited on the base material 3, which continuously runs around the circumference of the rotational support member 2.

If need be, the CVD apparatus may have a configuration in which a plurality of reactors 9 for performing CVD are provided in the vacuum chamber 1.

Specifically, a plurality of reactors 9 for generating plasma and which have the construction mentioned above are disposed in the vacuum chamber 1 so that they each face the deposition base material 3 which travels on the surface of the rotational support member 2. CVD may be conducted sequentially by all or some of the reactors 9 to form a film having a desired thickness, or a plurality of types of films may be deposited sequentially in layers by the reactors 9, and thus the plurality of reactors 9 can be used selectively and alternately.

Next, a case where the apparatus of the present invention is applied to the deposition of a hard carbon protective film in the manufacture of magnetic recording media is described below.

The hard carbon protective film is formed on a magnetic layer of a deposition base material in which the magnetic layer is formed on a non-magnetic support member.

The magnetic layer is configured with a metallic magnetic thin-film which is formed by depositing, for example, a metallic magnetic material on a non-magnetic support member by means of a vacuum thin-film forming technique.

The non-magnetic support member may include a polyester film, a polyamide film, or a polyimide film and the like.

The metallic magnetic thin-film material may include a ferromagnetic metal, such as Fe, Co, Ni and the like, or a ferromagnetic alloy, such as Fe—Co, Co—O, Fe—Co—Ni, Fe—Cu, Co—Cu, Co—Au, Co—Pt, Mn—Bi, Mn—Al, Fe—Cr, Co—Cr, Ni—Cr, Fe—Co—Cr, Co—Ni—Cr, Fe—Co—Ni—Cr and the like.

The metallic magnetic thin-film may be of either a single-layer film structure or a multi-layer film structure.

In order to improve adhesion and the control of the coercive force, a foundation layer or an intermediate layer may be provided between the non-magnetic support member and the metallic magnetic thin-film or between the individual layers in the case of the metallic magnetic thin film of a multi-layer film structure.

Further, in order to improve, for example, corrosion resistance, the surface and thereabouts of the metallic magnetic thin-film may be made an oxide.

The vacuum thin-film forming technique for depositing the metallic magnetic thin-film includes a vacuum deposition (evaporation) process in which a metallic magnetic material is heated and evaporated under vacuum conditions and then deposited on a non-magnetic support member, and an ion plating process in which a metallic magnetic material is evaporated during discharge. In addition, known methods may be used, such as so-called physical vapor deposition (PVD) techniques, which include a sputtering process in which a glow discharge occurs in an atmosphere containing, for example, mainly argon gas, where argon ions produced therein are bombarded against a target surface to sputter atoms from the target.

The hard carbon protective film can thus be formed on the magnetic layer.

The hard carbon protective film is a carbon film having a diamond structure, i.e., a so-called diamond-like carbon film. Carbon having a graphite structure and carbon having a diamond structure are known, and peaks characteristic of the respective carbon structures are observed when their Raman spectrums are measured. The diamond-like carbon film as used in the present invention refers to a carbon film at least part of which has a diamond structure, and in which peaks characteristic of a diamond structure is observed in a Raman spectrum thereof. Generally, a Raman spectrum of a diamond-like carbon film would show both peaks characteristic of a graphite structure and peaks characteristic of a diamond structure.

The hard carbon protective film described above is deposited by the apparatus of the present invention.

In this case, the deposition base material 3 corresponds to the non-magnetic support member having a metallic magnetic thin-film formed thereon as a tape-formed magnetic layer, and, as mentioned above, while continuously moving the deposition base material 3 around the rotational support member 2 and maintaining a predetermined tension in the deposition base material 3, the hard carbon protective film is continuously deposited on the metallic magnetic thin-film.

A reactant gas for forming the hard carbon film, for example, a hydrocarbon gas, such as ethylene or propane, or a gasified liquid of toluene or the like is fed to the reactor 9 from the reactant gas inlet 8.

On the other hand, the DC power source 11 provided outside the vacuum chamber 1 is connected to the discharge electrode 7, and a voltage of +500 to 2,000 V is applied to the discharge electrode 7.

In this case, too, a plurality of reactors 9 can be provided, and film deposition can be performed in layers to form a hard carbon protective film of a desired thickness.

When a voltage is applied to the discharge electrode 7, plasma is generated mainly in the reactor 9 between the discharge electrode 7 and the metallic magnetic thin-film on the non-magnetic support member held around the rotational support member 2. Then, the reactant gas fed to the reactor 9 is decomposed due to the energy of the generated plasma and becomes deposited on the metallic magnetic thin-film on the non-magnetic support member to form the hard carbon protective film.

If desired, various layers can be additionally formed. For example, if required, a back coat layer may be formed on a surface of the non-magnetic support member opposite the surface on which the magnetic layer is formed, an undercoat layer may be formed between the non-magnetic support member and the magnetic layer, or a lubricant layer may be formed on the magnetic layer.

For the non-magnetic pigments and resin binders contained in the back coat layer, as well as the material for the lubricant layer, any conventionally known material may be used.

Thus, magnetic recording media can be manufactured.

In the apparatus of the present invention, the reactor 9 has a construction such that the cylindrical inner wall structure 92 is disposed in the outer housing 91 so as to surround a section where plasma is generated, i.e., a section where the reaction product is likely to adhere. Therefore, when a film is deposited as mentioned above, most of the dirt adheres to the inner wall of the cylindrical inner wall structure 92, and in practice, mainly to the inner wall near the opening portion 92a.

The cylindrical inner wall structure 92 is separable from the outer housing 91. Therefore, dirt can easily be cleaned off by merely cleaning the cylindrical inner wall structure 92, which is simple in shape and in structure.

Next, the deposition of a hard carbon protective film on a metallic magnetic thin-film layer using an embodiment of the plasma CVD apparatus of the present invention will be described with reference to the following examples.

### EXAMPLE 1

First, a Co single-layer metallic magnetic thin-film was deposited on a non-magnetic support member comprising polyethylene terephthalate (PET) of a thickness of 6 μm by an oblique-angle vapor deposition process while feeding oxygen gas.

The deposition conditions were as follows.

| | |
|---|---|
| Incident angle for deposition: | 45 to 90° |
| Gas fed: | Oxygen gas |
| Degree of vacuum during deposition: | 2 × 10⁻² Pa |
| Thickness: | 200 nm |

Subsequently, a hard carbon protective film was deposited on the Co—O single-layer metallic magnetic thin-film using an embodiment of the plasma CVD apparatus of the present invention shown in FIGS. 1 and 2 to prepare a sample tape.

Here, a plurality of reactors 9 were used and the deposition conditions in all of the reactors 9 were the same. The thickness of the film deposited by each reactor was set to be 10 nm to prepare a hard carbon protective film of a desired thickness.

Glass having a thermal conductivity of 14.2 [W·m⁻¹·k⁻¹] or above was used for the cylindrical inner wall structure 92 of each of the reactors 9.

Operational conditions of the reactors 9 were as follows.

| | |
|---|---|
| Gas fed: | Ethylene/argon mixed gas |
| | (Argon rate: 20 vol %) |
| Flow rate: | 150 sccm |
| Reaction pressure: | 30 Pa |
| Power | DC 1.2 kV |

### EXAMPLE 2

A hard carbon protective film was deposited in a manner similar to that of Example 1 except in that the cylindrical inner wall structure 92 was configured with porcelain.

### EXAMPLE 3

A hard carbon protective film was deposited in a manner similar to that of Example 1 except in that the cylindrical inner wall structure 92 was configured with aluminum.

### EXAMPLE 4

A hard carbon protective film was deposited in a manner similar to that of Example 1 except in that the cylindrical inner wall structure 92 was configured with magnesium.

### COMPARATIVE EXAMPLE 1

A hard carbon protective film was deposited in a manner similar to that of Example 1 except in that the cylindrical inner wall structure 92 was configured with mica.

### COMPARATIVE EXAMPLE 2

A hard carbon protective film was deposited in a manner similar to that of Example 1 except in that the cylindrical inner wall structure 92 was configured with polycarbonate.

### COMPARATIVE EXAMPLE 3

Using a plasma CVD apparatus having a conventional reactor, in other words, a reactor which has an inseparable structure unlike the reactor in the present invention in which the outer housing 91 and the cylindrical inner wall structure 92 are configured so as to be separable, a hard carbon protective film was deposited under similar deposition conditions as those employed in Example 1 to prepare a sample tape.

In each of the Examples and the Comparative Examples, during the deposition of the carbon protective film, the reaction product adheres to the reactor.

Therefore, the reactor 9 must be cleaned occasionally.

In the apparatus of the present invention, the reactor 9 has a construction such that the cylindrical inner wall structure 92 is disposed in the outer housing 91 so as to surround a section in which plasma is generated, i.e., a section where the reaction product is likely to adhere. Therefore, when a film is deposited as mentioned above, most of the dirt adheres to the inner wall of the cylindrical inner wall structure 92, and in practice, mainly to the inner wall near the opening portion 92a.

According to the present invention, the cylindrical inner wall structure 92 is separable from the outer housing 91. Further, the cylindrical inner wall structure 92 has a simple tubular or cylindrical shape and structure. Therefore, the operation for separating the cylindrical inner wall structure 92 from the outer housing 91 and cleaning it can be achieved very easily in a shorter time.

In other words, reactors generally have many parts and thus have a complicated construction. Therefore, cleaning conventional reactors is troublesome and time consuming, whereas in the apparatus of the present invention, most of the parts are left with the outer housing 91, and therefore the handling and cleaning of the cylindrical inner wall structure 92 are made much easier.

Further, by preparing a plurality of cylindrical inner wall structures 92 so that spare cylindrical inner wall structures 92 which are already cleaned can be provided readily, intervals during which the CVD apparatus cannot be used due to cleaning can be reduced considerably.

In contrast, in Comparative Example 3 in which a conventional CVD apparatus was used, the whole of the reactor had to be cleaned and therefore the CVD apparatus could not be used during cleaning. In addition, the reactor has a complicated structure with its various parts, and hence the actual cleaning time for the reactor including the handling of the complicated parts was considerably prolonged, and the interval during which the CVD apparatus could not be used reached 0.7 hours. Therefore, the time required for the apparatus to stabilize for the succeeding CVD operation also became longer.

Further, because the structure of the portion to be cleaned in the reactor is complicated, the time taken for cleaning became longer, thereby lowering operational efficiency.

The cylindrical inner wall structure 92 can be cleaned extremely well by merely immersing it in, for example, a 1:1 mixture of nitric acid and hydrofluoric acid.

The temperatures during film deposition in the reactors in Examples 1 to 4 and Comparative Examples 1 and 2 are shown in FIG. 3. These temperatures were measured using commercially available thermo seals.

As can be seen from FIG. 3, in each of the Examples, the temperature rise in the reactor during deposition was small.

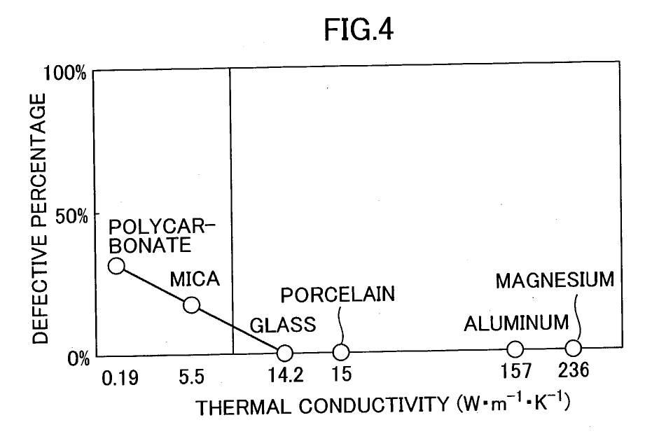

Further, in FIG. 4, with respect to the sample tapes in Examples 1 to 4 of the present invention and in Comparative Examples 1 and 2, the relationship between the measurement results of the defective percentage due to wrinkles and the thermal conductivity of each of the cylindrical inner wall structures 92 in the reactors 9 is shown.

As can be seen from FIG. 4, when the material of the cylindrical inner wall structure 92 has a thermal conductivity of 14.2 [W·m⁻¹·k⁻¹] or above, the defective percentage is improved.

It is conceivable that this is related to the suppression of the rise in temperature as shown in FIG. 3 to reduce radiant heat.

In the examples of the apparatus of the present invention mentioned above, descriptions were given mainly with respect to the deposition of a hard carbon protective layer, but an apparatus of the present invention can be applied to the deposition of other kinds of films by plasma CVD.

It is understood that the invention is not limited to the specific examples and embodiments, including those shown in the drawings, which are intended to assist a person skilled in the art in practicing the invention. Many modifications and improvements may be made without departing from the scope of the invention, which should be determined based on the claims below, including any equivalents thereof.

What is claimed is:

1. A plasma chemical vapor deposition apparatus, comprising:
a vacuum chamber;
a supporting portion provided in said vacuum chamber and which supports a deposition base material on which plasma chemical vapor deposition (plasma CVD) is performed; and
a reactor for generating plasma, wherein
said reactor includes an inlet for a plasma CVD reactant gas, and comprises an outer housing having an opening in the direction of said deposition base material on said supporting portion, and a cylindrical inner wall structure having an opening in the same direction as said opening of said outer housing and which is inserted in said outer housing so as to surround a section where plasma is generated and so as to be freely attachable and detachable to and from said outer housing,
said cylindrical inner wall structure has electrically insulative properties and has at least the surface of said cylindrical inner wall structure formed with an insulative material, and
said cylindrical inner wall structure has a grid electrode disposed in another opening portion on a side opposite said opening of said cylindrical inner wall structure.

2. The plasma chemical vapor deposition apparatus according to claim 1, wherein said cylindrical inner wall structure comprises a material having a thermal conductivity of 14.2 [W·m⁻¹·k⁻¹] and above.

3. The plasma chemical vapor deposition apparatus according to claim 1, wherein said cylindrical inner wall structure has a composite structure including a metal and an insulative material covering the surface of said metal.
